(19) United States
(12) Patent Application Publication
(10) Pub. No.: US 2007/0018310 A1
(43) Pub. Date: Jan. 25, 2007

(54) Semiconductor device and manufacturing method thereof

(75) Inventor: Toshihisa Sato, Kawasaki (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU LIMITED, Kawasaki (JP)

(21) Appl. No.: 11/259,194

(22) Filed: Oct. 27, 2005

(30) Foreign Application Priority Data
Jul. 22, 2005 (JP) 2005-212456

(51) Int. Cl. H01L 21/50; H01L 23/34

(52) U.S. Cl. 257/706; 257/712; 438/125

(57) ABSTRACT

In a semiconductor device, a semiconductor element is mounted on a package substrate, and a heat dissipating member is laid above the semiconductor element and the package thereby sealing the semiconductor element. Resin is filled into the space defined by the semiconductor element, the package substrate, and the heat dissipating member such that there are no gaps.

### BACKGROUND OF THE INVENTION

1. Field of the Invention

The present invention relates to a semiconductor device and a method of manufacturing the semiconductor device.

2. Description of the Related Art

The recent semiconductor elements are more densely integrated than they used to be in the past. As a result, the recent semiconductor elements consume more power and release more heat than ever before. The released heat damages the semiconductor elements. Therefore, a heat dissipating member such as a heat spreader, a lid, or a heat sink is provided on a semiconductor device on which semiconductor elements are mounted. The heat dissipating member dissipates the heat released from the semiconductor elements to the outside to thereby projecting the semiconductor device from the heat.

The heat dissipating member is directly mounted on a back surface of a semiconductor element, and is exposed to the upper surface of the semiconductor device. Therefore, the heat generated in the semiconductor element is directly transmitted to the heat dissipating member, and is dissipated to the outside air from the heat dissipating member. With this arrangement, the semiconductor element can be cooled efficiently.

In this high-performance high-heat large scale integration (LSI) package, an LSI element and a heat dissipating member are connected together with a metal (solder), to increase heat transmission from the back surface of the LSI element to the heat dissipating member. For this metal connection, solder containing lead such as an Sn—Pb system (Sn—Pb, Sn—Pb—Ag), and solder containing no lead such Au—Sn, Au—Si, and Au—Ga are used.

Japanese Patent Application Laid-open No. 2004-260138 discloses a first conventional semiconductor device having a semiconductor chip flip-chip connected to a mounting substrate. This configuration allows decreasing generation of a warp in the substrate, and suppressing destruction of solder bumps for connecting between the semiconductor chip and the substrate in a temperature cycle test, or occurrence of cracks in the substrate.

According to the first conventional semiconductor device, the semiconductor substrate includes a semiconductor chip, a mounting substrate having this chip flip-chip connected to the substrate, a first filling section having an under-fill part and a fillet formed with a first resin, a reinforcing member, a first adhesive, a lid, and a second filling section formed with a second resin having a smaller coefficient of thermal expansion than that of the first resin.

Japanese Patent Application Laid-open No. H6-61383 discloses a second conventional semiconductor device having a flip-chip element sealed into a ceramic package in a face down manner. Heat dissipation of the flip-chip is satisfactory, and the flip-chip element and a pad of the ceramic package are connected in high reliability.

According to the second conventional semiconductor device, the flip-chip element is filled into the ceramic package, which has a recess opened at the top, in a face down manner. The recess is sealed with a metal lid. The semiconductor device has a buffer resin that is filled into between the flip-chip element and a bottom surface of the recess and surrounds the bumps, a heat-resistant resin that is filled in a lower part of the recess so that the upper surface of the flip-chip element is exposed, and solder that is filled into the recess so that the upper surface of the flip-chip element and the lower surface of the metal lid are closely adhered together and the solder is present between the flip-chip element and the metal lid.

However, when the coefficient of thermal expansion of one constituent element is considerably different from that of other constituent element of an organic package substrate like in the conventional configuration, a warp can occur in the substrate due to residual stress of the connected parts, and a distortion or a cracking occurs in the junction of parts having mutually different physical properties. In other words, it is difficult to reliably maintain a stable connection state for a long time.

In the first conventional semiconductor device, an air gap is present between the second filling section and the lid. Therefore, a distortion tends to occur at the boundary between the air gap and the parts due to the application of thermal stress. This air gap decreases radiation efficiency of semiconductor chips.

In the second conventional semiconductor device, solder is present between the flip-chip element and the metal lid. Because the heat-resistant resin is not directly closely adhered to the metal lid, a distortion in the vertical direction of the metal lid due to the application of the thermal stress cannot be suppressed.

### SUMMARY OF THE INVENTION

It is an object of the present invention to at least solve the problems in the conventional technology.

According to one aspect of the present invention, a semiconductor device includes a semiconductor element; a package substrate on which the semiconductor element is mounted; and a heat dissipating member that is connected to the semiconductor element and to the package substrate any of directly or via a reinforcing member while forming a space around the semiconductor element; and at least one opening that communicates to the space from outside. Moreover, resin is filled into the space via the opening such that the resin completely fills the space, and the resin is cured after filling.

According to another aspect of the present invention, a semiconductor device includes a semiconductor element enclosed between a package substrate and a heat dissipating member; and a layer of resin in a space between any one of the semiconductor element, the package substrate, and the heat dissipating member.

According to still another aspect of the present invention, a method of manufacturing a semiconductor device includes mounting a semiconductor element on a package substrate; filling an underfill in between the package substrate and the semiconductor element, and curing the underfill; laying a heat dissipating member on the semiconductor element and the package substrate, thereby sealing the semiconductor element between the heat dissipating member and the package substrate; completely filling a space defined by the semiconductor element, the package substrate, and the heat dissipating member with a resin; and curing the resin filled in the space.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a cross section of relevant parts of a semiconductor device according to an embodiment of the present invention;

FIG. 2 is a perspective and cut view of the semiconductor device shown in FIG. 1;

FIG. 3 to FIG. 8 are cross sections for explaining a method of manufacturing the semiconductor device shown in FIG. 1;

FIG. 9 is a cross section of relevant parts of a semiconductor device having a resin-filling slit on the heat dissipating member; and

FIG. 10 is a cross section of relevant parts of a semiconductor device having a heat sink as the heat dissipating member.

### DETAILED DESCRIPTION OF THE PREFERRED EMBODIMENTS

Exemplary embodiments of the present invention will be explained in detail with reference to the accompanying drawings. Note that the invention is not limited by the embodiments.

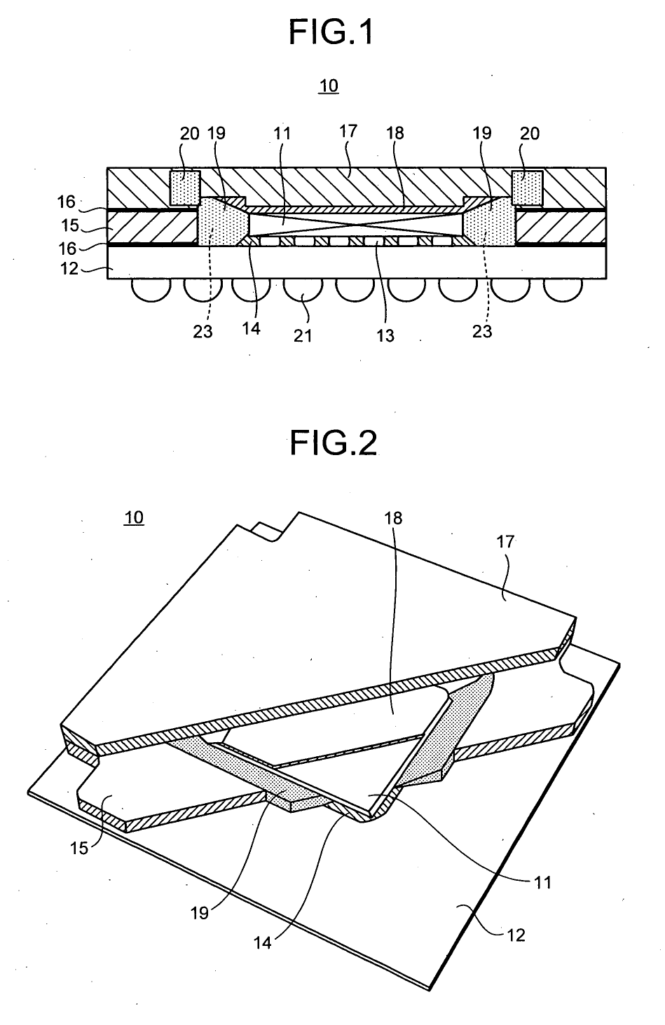

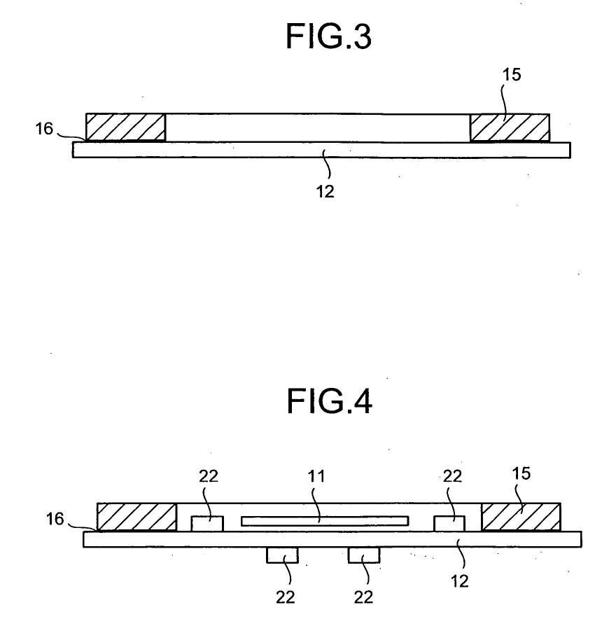

FIG. 1 is a cross section of relevant parts of a semiconductor device 10 according to an embodiment of the present invention. FIG. 2 is a perspective cut view of the semiconductor device 10. The semiconductor device 10 includes an LSI element 11, which is a semiconductor element, a package substrate 12 on which the LSI element 11 is mounted, and a heat dissipating member 17 that is connected to the LSI element 11 with a metal. The heat dissipating member 17 is connected to the package substrate 12 via a frame-shaped stiffener (a reinforcing member) 15. The heat dissipating member 17, the stiffener 15, and the package substrate 12 form a package space (a predetermined space) 23 around the LSI element 11. Moreover, the heat dissipating member 17, the stiffener 15, and the package substrate 12 seal the LSI element 11.

An adhesive sheet 16 is used to fix the heat dissipating member 17 and the stiffener 15 to each other, and to fix the stiffener 15 and the package substrate 12 to each other. The LSI element 11 rests on plural bumps 13 formed on the package substrate 12. An underfill 14 is filled in between the bumps 13.

Resin filling openings 20 from which a resin 19, such as thermosetting resin, can be filled into the package space 23 are provided in the heat dissipating member 17. The resin 19 is filled in such a manner that it completely fills the package space 23. After filling, the resin 19 is cured. A lid is used as the heat dissipating member 17.

The package substrate 12 can be a flip chip ball grid array (FC-BGA), a flip chip land grid array (FC-LGA) package, or a flip chip pin grid array (FC-PGA) package. When the package substrate 12 is the FC-BGA, an organic substrate material can be used apart from a ceramic material containing any of Al₂O₃, AlN, and glass. For example, a glass ceramic substrate or an organic substrate having a thickness of 0.4 millimeter to 0.7 millimeter can be used as the package substrate 12.

The underfill 14 can be a material including a resin containing epoxy resin. It is preferable, but not necessary, that a coefficient of thermal expansion of the underfill 14 is about 1,500 ppm to 2,000 ppm, and is heat cured usually at about 150° C.

Copper or stainless material having a coefficient of thermal expansion substantially equal to that of the package substrate 12 is used for the material of the stiffener 15. A material made of epoxy resin is used for the adhesive sheet 16.

Copper or Al having satisfactory thermal conductivity, a composite material using copper or Al as a base, or a carbon composite material can be used for the material of the heat dissipating member 17. In this embodiment, oxygen-free high conductivity copper is used. Solder containing In—Ag as a main component is used for the material of a metal connecting material 18.

The resin 19 has a coefficient of thermal conductivity (for example, 20 ppm to 40 ppm) that is different from that of the underfill 14.

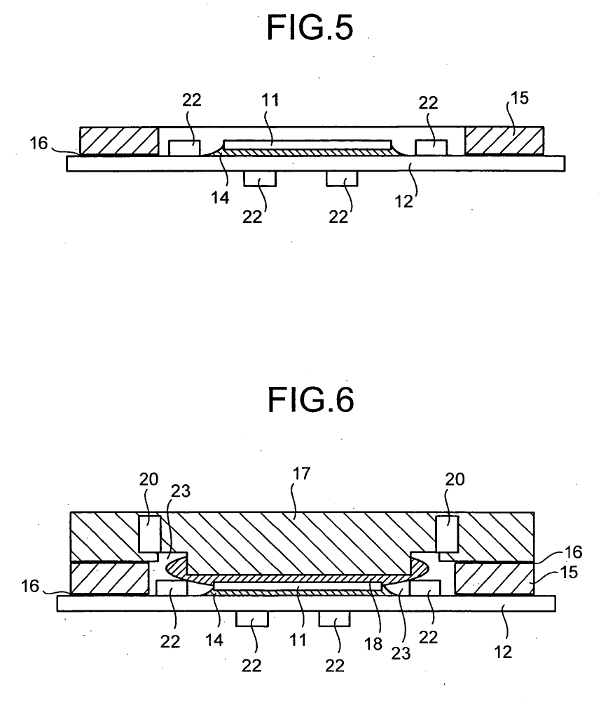

A method of manufacturing the semiconductor device 10 is explained with reference to FIG. 3 to FIG. 8. FIG. 3 depicts a state in which the stiffener 15 adhered to the package substrate 12 with the adhesive sheet 16. FIG. 4 depicts a state in which the LSI element 11 and electronic components 22 are mounted on the package substrate 12. FIG. 5 depicts a state in which the underfill 14 filled, in the bumps 13 (not shown). The underfill 14 is cured in this state.

FIG. 6 depicts a state in which the heat dissipating member 17 is soldered to the LSI element 11. FIG. 7 depicts a state in which the resin 19 is filled into the package space 23 through the resin filling openings 20. FIG. 8 depicts a state in which ball grid array (BGA) balls 21 are mounted on the package substrate 12. Thus, the semiconductor device 10 becomes ready.

Precisely, as shown in FIG. 3, first, the stiffener 15 is adhered to the package substrate 12 using the adhesive sheet 16. This is a reinforcing member adhering step.

The stiffener 15 is adhered to the package substrate 12 using the adhesive sheet 16 by applying a pressure of about 2 kg/cm². To obtain a uniform adhesion thickness, glass fiber or inorganic filler is filled in the adhesive material.

Thereafter, as shown in FIG. 4, the LSI element 11 is flip-chip mounted on the package substrate 12. When the electronic components 22 such as a capacitor and a chip resistor need to be mounted on the surface on which the LSI element 11 is mounted, these electronic components 22 are also connected at the same time. This is a semiconductor element mounting step.

When a solder material of an electrode is Sn—Ag, for example, the electrode is mounted at a peak temperature of a temperature profile of 235 to 245° C. At present, many packages employ a method that the electrode of the LSI element 11 is formed with Sn—Pb solder containing Pb by 90 percent or more, and the electrode is connected to the package substrate 12 with Sn-37 Pb (eutectic crystal) that is soldered in advance. These packages are also soldered at a peak temperature usually at around 230° C.

As shown in FIG. 5, after the LSI element 11 is mounted on the package substrate 12, the underfill 14 is filled into between the bumps 13 on the surface of the flip-chip mounted circuit (see FIG. 1), and the underfill 14 is cured. This is an underfill filling and curing step. This underfill 14 is cured at a temperature usually at around 150° C.

As shown in FIG. 6, after the underfill 14 is filled and cured, the heat dissipating member 17 is connected to the LSI element 11 with the metal connecting material 18. This is a heat dissipating member connecting step.

To carry out the metal connection, the surface of the material of the heat dissipating member 17 needs to be metalized for the soldering. For example, Ni and Au are electrolytically plated on the surface of the oxygen-free copper material according to this embodiment to prevent wetness and oxidization. The Ni has a metal thickness of 3 micrometers, and Au has a metal thickness of 0.3 micrometer.

The back surface of the FC-BGA package for connecting the heat dissipating member 17 at the LSI element 11 side is formed with a metal layer (metalized) in the wafer process in advance. This metal layer is Cu, Au, or the like. In this embodiment, Ti 5000 Å of adhered metal is formed, and Au is formed in the thickness of 0.3 micrometer on the Ti.

As shown in FIG. 7, the resin 19 having a coefficient of thermal expansion substantially the same as that of the package substrate 12 is filled into the package space 23 sealed with the heat dissipating member 17, from the resin filling opening 20. The resin 19 is filled into the package space 23 completely so as not to have any gap in the package space. This is a resin filling step. By decreasing a difference between the coefficient of thermal expansion of the package substrate 12 and the coefficient of thermal expansion of the resin 19, thermal stress can be decreased when it is applied.

The resin 19 is cured usually at a temperature around 150° C. in the resin curing step.

As shown in FIG. 8, after the resin 19 is cured, the BGA balls 21 are mounted on the package substrate 12 according to needs.

For example, when the packaging solder for these parts is a low-melting point solder such as a general Sn-37 Pb (eutectic crystal) solder, even a reflow temperature increases to around 250° C. corresponding to the Pb despite the reflow temperature of 230° C. or below, a thermal behavior of the package can be decreased. Therefore, the reflow temperature limit can be mitigated.

As explained above,-the package space 23 is completely filled with the resin 19, and the resin 19 is cured. As a result, the resin 19 firmly adheres to a part of the heat dissipating member 17, a part of the metal connecting material 18, the side surfaces of the semiconductor element 11, an edge of the underfill 14, and a part of the stiffener 15.

Because the corresponding parts are restricted by the resin 19, stress can be decreased, and thermal stress due to a secondary connection (the mounting of the BGA balls 21) can be applied by many times. Consequently, a warp in the package substrate 12 and a distortion at a junction between the parts having different physical properties can be corrected, thereby dispersing and decreasing stress applied to a junction between the parts.

Furthermore, a reduction in the reliability of semiconductor device 10 due to a mismatch between the coefficient of thermal expansion of the heat dissipating member 17 and the coefficient of thermal expansion of the LSI element 11 can be suppressed. Therefore, Cu or Al having satisfactory thermal conductivity can be used for the material of the heat dissipating member 17, thereby further improving heat dissipation.

The resin 19 is filled into the package space 23 without a gap, and the resin 19 is also closely adhered to a part of the metal connecting material 18 without a gap. Therefore, thermal resistance decreases substantially from that according to the conventional technique, thereby improving heat dissipation efficiency. Consequently, the metal connecting material 18 having high thermal conductivity corresponding to high heat dissipation of the LSI element 11 can be provided.

Because the resin filling openings 20 are provided on the side surfaces of the heat dissipating member 17, the following effects can be obtained. Usually, on the side surfaces of the heat dissipating member 17 provided with the resin filling openings 20, other constituent elements are not provided. Therefore, even when the thermosetting resin 19 slightly overflowed from the resin filling openings 20 is not removed, this resin does not interfere with the manufacturing of the semiconductor device 10. Consequently, a step of removing the surplus resin is not necessary, which further simplifies the manufacturing process.

The resin filling openings 20 can be provided on side surfaces of the stiffener 15 instead of the side surfaces of the heat dissipating member 17. Alternatively, the resin filling openings 20 can be provided on both the side surfaces of the heat dissipating member 21 and the stiffener 15. In these cases, effects similar to the above can be also obtained.

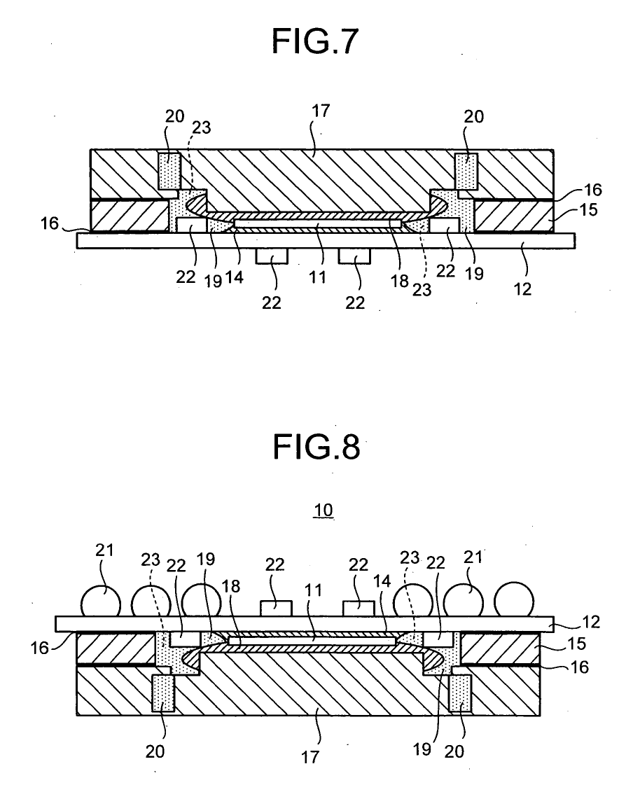

The resin filling opening 20 can be provided as a slit 20a as shown in FIG. 9. In this case, effects similar to the above can be also obtained. In this example, a heat spreader is used for the heat dissipating member 17.

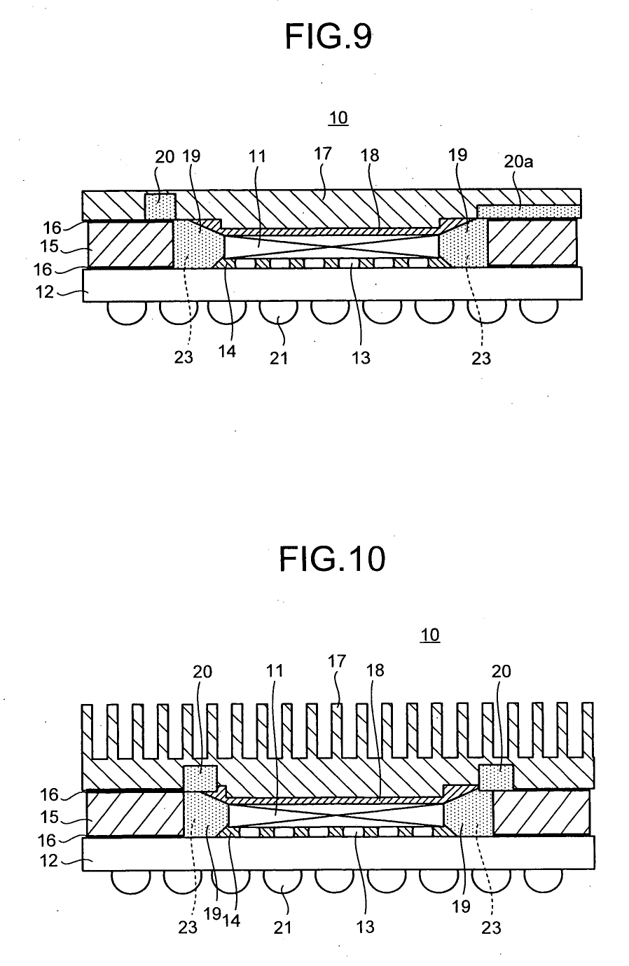

The heat dissipating member 17 explained above is a lid. However, a heat sink can be used instead of the lid, as shown in FIG. 10. In this case, effects similar to the above can be also obtained.

The stiffener 15 can be omitted. In other words, the heat dissipating member 17 can be directly connected to the package substrate 12.

The adhesive sheet 16 used for connecting the stiffener 15 can be used according needs, and other adhering unit can be also used.

According to the present invention, a space around the semiconductor device is completely filled with a resin. Therefore, stress can be decreased, and thermal stress due to a secondary connection can be applied by many times. Accordingly, a warp in the package substrate and a distortion in a junction between the parts having different physical properties can be corrected, thereby dispersing and decreasing stress applied to each junction. The resin can be filled into the space without a gap, and is also closely adhered to a part of the heat dissipating member without a gap. As a result, thermal resistance can be substantially decreased from that according to the conventional technique, thereby improving heat dissipation efficiency. Consequently, the invention can solve problems due to high heat generation in a semiconductor element.

According to the present invention, by decreasing a difference between the coefficient of thermal expansion of the package substrate and the coefficient of thermal expansion of the thermosetting resin, stress applied to the soldered part of the semiconductor element can be decreased.

According to the present invention, usually, other constituent elements are not provided on the side surfaces on which the resin filling openings are provided. Therefore, even though the thermosetting resin slightly overflowed from the resin filling openings is not removed, this resin does not become interference in the manufacturing of the semiconductor device. Consequently, a step of removing surplus resin is not necessary, which further simplifies the manufacturing process.

According to the present invention, even when a general heat dissipating member is used, heat dissipation efficiency can be improved. Consequently, the invention can solve problems due to high heat generation in a semiconductor element.

According to the present invention, it is possible to provide a method of manufacturing a semiconductor device capable of suppressing the occurrence of a warp in a substrate due to the application of a thermal stress during a manufacturing of the semiconductor device and a distortion at a junction between parts having different physical properties, capable of dispersing and decreasing stress applied to a junction between the parts, and capable of decreasing problems due to high heat generation in a semiconductor element.

Although the invention has been described with respect to a specific embodiment for a complete and clear disclosure, the appended claims are not to be thus limited but are to be construed as embodying all modifications and alternative constructions that may occur to one skilled in the art that fairly fall within the basic teaching herein set forth.

What is claimed is:

1. A semiconductor device comprising:
a semiconductor element;
a package substrate on which the semiconductor element is mounted; and
a heat dissipating member that is connected to the semiconductor element and to the package substrate any of directly or via a reinforcing member while forming a space around the semiconductor element; and
at least one opening that communicates to the space from outside, wherein
resin is filled into the space via the opening such that the resin completely fills the space, and the resin is cured after filling.

2. The semiconductor device according to claim 1, wherein the resin is a thermosetting resin.

3. The semiconductor device according to claim 1, wherein a coefficient of thermal expansion of the resin is substantially the same as that of the package substrate.

4. The semiconductor device according to claim 1, wherein the opening is provided on a side surface of the heat dissipating member.

5. The semiconductor device according to claim 1, wherein the opening is provided on a side surface of the reinforcing member.

6. The semiconductor device according to claim 1, wherein the heat dissipating member is any one of a lid, a heat spreader, and a heat sink.

7. A semiconductor device comprising:
a semiconductor element enclosed between a package substrate and a heat dissipating member; and
a layer of resin in a space between any one of the semiconductor element, the package substrate, and the heat dissipating member.

8. The semiconductor device according to claim 7, further comprising at least one path that communicates from outside to the space to be used for filling resin in the space.

9. The semiconductor device according to claim 8, wherein the path is formed in the heat dissipating member.

10. A method of manufacturing a semiconductor device, comprising:
mounting a semiconductor element on a package substrate;
filling an underfill in between the package substrate and the semiconductor element, and curing the underfill;
laying a heat dissipating member on the semiconductor element and the package substrate, thereby sealing the semiconductor element between the heat dissipating member and the package substrate;
completely filling a space defined by the semiconductor element, the package substrate, and the heat dissipating member with a resin; and
curing the resin filled in the space.

11. The method according to claim 10, further comprising:
adhering a reinforcing member to the package substrate before laying the heat dissipating member on the semiconductor element so that at the laying the heat dissipating member is laid on both the semiconductor element and the reinforcing member and the space is defined by the semiconductor element, the package substrate, the heat dissipating member, and the reinforcing member.
